(19) United States
(12) Patent Application Publication
(10) Pub. No.: US 2023/0412124 A1
(43) Pub. Date: Dec. 21, 2023

(54) POWER RECEIVING SYSTEM

(71) Applicant: Hitachi, Ltd., Tokyo (JP)

(72) Inventors: Tsukasa FUNANE, Tokyo (JP); Koichi WATANABE, Tokyo (JP); Yosuke TANABE, Tokyo (JP); Jun HAYAKAWA, Tokyo (JP)

(21) Appl. No.: 18/112,752

(22) Filed: Feb. 22, 2023

(30) Foreign Application Priority Data
Jun. 20, 2022 (JP) 2022-098563

(51) Int. Cl. H02S 40/44

(52) U.S. Cl. CPC H02S 40/44; H10N 10/00

(57) ABSTRACT

Provided is a power receiving system having an increased energy conversion efficiency. The power receiving system according to the present disclosure includes a power converter that receives electromagnetic waves transmitted from space and converts the electromagnetic waves into electric power; a thermal energy converter that is disposed adjacent to the power converter and converts thermal energy generated in the power converter; and a controller that controls operation of the thermal energy converter based on an energy intensity distribution of the electromagnetic waves.

### CROSS REFERENCE TO RELATED APPLICATIONS

The present application claims priority from Japanese patent application JP 2022-098563, filed on Jun. 20, 2022, the entire content of which is hereby incorporated by reference into this application.

### BACKGROUND

### Technical Field

The present disclosure relates to a power receiving system.

### Background Art

One of renewable energy proposals is a space solar power system (satellite/station) (SSPS or SPS) that uses a solar panel installed on a satellite or the like to convert solar energy in space into electrical energy and transmits electric power to Earth using electromagnetic wave, such as microwave, or laser light (see, for example, JP 3584925 B and JP 2003-153565 A). The space solar power system has received much attention due to its advantages over the solar power generation on Earth in that the space solar power system can generate electric power day and night without being affected by weather and has a high solar power density. Various techniques of the space solar power system have been proposed to efficiently transfer electric power generated in space to Earth.

For example, JP 3584925 B discloses a technique of the space solar power system in which the satellite including solar cells that convert sunlight into electrical energy transmits microwaves based on the generated power to antennas on Earth, and the antennas on Earth convert the received microwaves into electric power. This space solar power system includes a power generation satellite group made up of a plurality of power generation satellites each including a transmitting antenna, and the transmitting antennas of the power generation satellite group as element antennas form an array antenna. JP 2003-153565 A discloses a technique of using energy leaking from a laser optical system and thus deliberately using a translucent-type reflector, and placing solar cells behind the reflector to generate power using the energy of laser light passing therethrough.

However, the conventional space solar power systems still need improvement to increase the energy conversion efficiency. In particular, energy not converted into electric power by a receiving antenna and a power converter results in exhaust heat and is not effectively used in practice. JP 3584925 B and JP 2003-153565 A do not propose a technique of increasing the energy conversion efficiency through the effective use of such exhaust heat in the receiving unit.

### SUMMARY

The present disclosure proposes a power receiving system having an increased energy conversion efficiency through the effective use of exhaust heat on Earth.

In view of the foregoing, the power receiving system according to the present disclosure includes: a power converter that receives electromagnetic waves transmitted from space and converts the electromagnetic waves into electric power; a thermal energy converter that is disposed adjacent to the power converter and converts thermal energy generated in the power converter; and a controller that controls operation of the thermal energy converter based on an energy intensity distribution of the electromagnetic waves.

According to the power receiving system of the present disclosure, it is possible to provide a power receiving system having an increased energy conversion efficiency through the effective use of exhaust heat on Earth.

### BRIEF DESCRIPTION OF THE DRAWINGS

FIG. 1 is a schematic diagram illustrating a schematic configuration of a space solar power system (power receiving system) according to a first embodiment;

FIG. 2 is a schematic diagram illustrating the schematic configuration of the space solar power system (power receiving system) according to the first embodiment;

FIG. 3 is a schematic diagram illustrating in more detail the structure of a thermal energy converter 400 and a controller 500 of the space solar power system (power receiving system) according to the first embodiment;

FIG. 4 is a schematic diagram illustrating a schematic configuration of a space solar power system (power receiving system) according to a second embodiment;

FIG. 5 is a schematic diagram illustrating a schematic configuration of a space solar power system (power receiving system) according to a third embodiment;

FIG. 6 is a graph illustrating the operation of the space solar power system (power receiving system) according to the third embodiment;

FIG. 7 is a schematic diagram illustrating a schematic configuration of a space solar power system (power receiving system) according to a fourth embodiment; and

FIG. 8 shows examples of microwave energy intensity distribution.

### DETAILED DESCRIPTION

In the following, embodiments of the present disclosure will be described with reference to the attached drawings. In the attached drawings, functionally identical elements may be designated with identical numerals. The attached drawings illustrate embodiments and implementation examples in accordance with the principles of the present disclosure. However, these are provided to assist an understanding of the present disclosure and should not be construed as limiting the present disclosure. It should be understood that the descriptions that follow are for exemplary purposes only, and do not in any way represent a limitation of the scope of the claims or application examples of the present disclosure.

While the embodiments are described in sufficient detail to enable a person skilled in the art to practice the present disclosure, it will be understood that other implementations or embodiments are also possible, and that various changes to configurations or structures and various substitutions of elements may be made without departing from the scope and spirit of the technical concepts of the present disclosure. Accordingly, the following descriptions are not to be interpreted in a limiting sense.

### First Embodiment

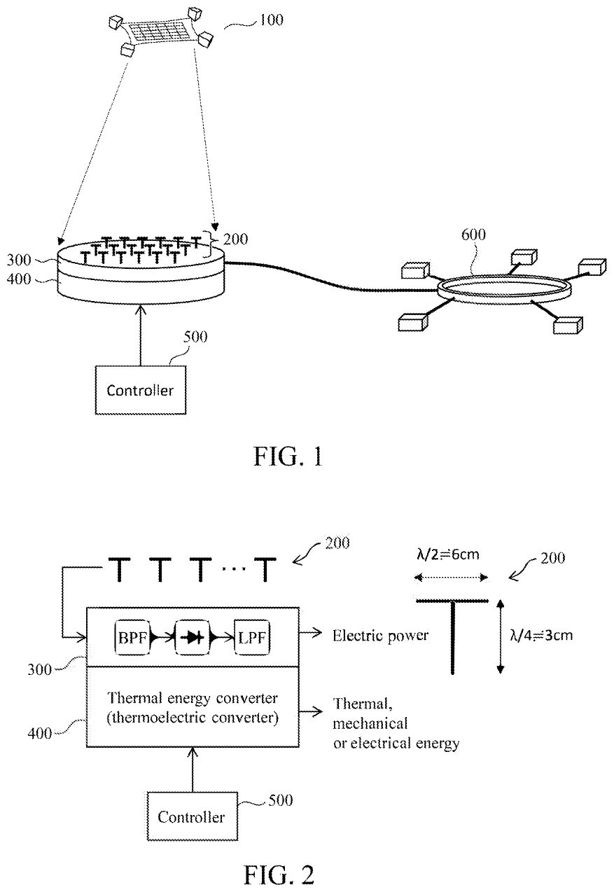

Referring to FIG. 1 and FIG. 2, a schematic configuration of a space solar power system (power receiving system) according to a first embodiment will be described. FIG. 1 shows the overall configuration of the space solar power system and FIG. 2 is a block diagram of the portion of the receiving antenna 200, the power converter 300, and the thermal energy converter 400. As shown in FIG. 1, this space solar power system includes a satellite 100, a receiving antenna 200, a power converter 300, a thermal energy converter 400, and a controller 500, and is configured to supply generated power to a power grid (load) 600.

In one example, the satellite 100 is a geostationary satellite that moves in a geostationary orbit (about 36,000 km above the equator) and includes a solar panel (for example, about 2.5 km×2.5 km) that converts sunlight into electric power. The satellite 100 is configured to convert electric power generated by the solar panel into microwaves (electromagnetic waves) with a frequency of 2.45 GHz (wavelength λ=12.2 cm) or 5.8 GHz (wavelength λ=5.17 cm), for example, and emit the microwaves at an energy orientation accuracy of about 1 μrad, for example, from the transmitting antenna to Earth. Specifically, though not shown, the satellite 100 includes a frequency converter that converts DC power generated by the solar panel into AC power corresponding to the frequency of microwaves, a microwave controller that controls the amplitude, frequency, and phase of the microwaves, and a transmitting antenna.

The receiving antenna 200 is placed on Earth, and includes a large number of dipole antennas arranged in an array across an area of 3 km×3 km, for example. Each of the dipole antennas may include, for example, a horizontal conductor that is about a half (about 6 cm when the frequency is 2.45 GHz) of the wavelength λ of the microwave in length and a vertical conductor that is about a quarter (about 3 cm when the frequency is 2.45 GHz) of the wavelength λ of the microwave in length. Here, instead of the dipole antenna, a patch antenna may be used.

The power converter 300 is made up of a combination of a band-pass filter, a rectifier circuit, and a low-pass filter, for example, and converts the microwaves received by the receiving antenna 200 into commercial electric power, for example. When the received microwave energy is converted into electrical energy, a conversion loss occurs in an electric circuit such as the rectifier circuit including diodes, and heat is generated. The thermal energy converter 400 is disposed adjacent to the power converter 300 and serves to convert the exhaust heat generated in the power converter 300 into other forms of energy (heat, electric power). As will be described later, the thermal energy converter 400 is configured such that its operation can be changed according to an intensity distribution of microwave energy from the satellite 100. The controller 500 is configured to acquire information about the microwave energy intensity distribution and control the operation of the thermal energy converter 400.

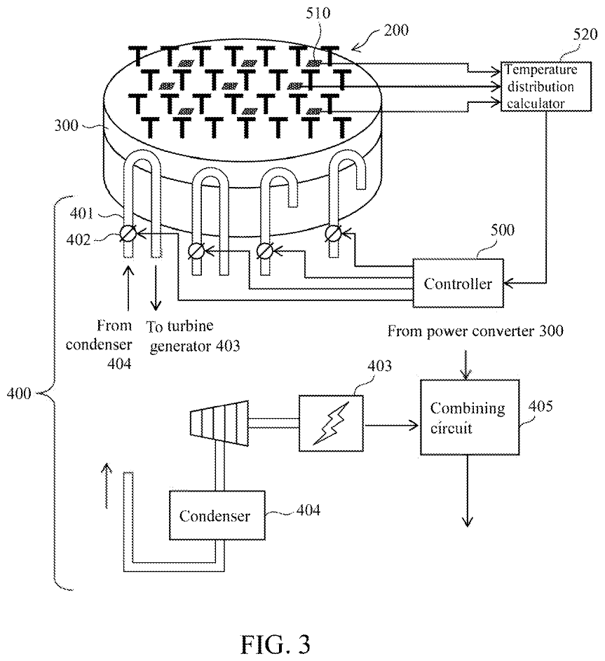

FIG. 3 is a schematic diagram illustrating in more detail the structure of the space solar power system of the first embodiment. In one example, the thermal energy converter 400 is configured to pass a heat conductive medium (for example, water) through the vicinity of the power converter 300, allow the heat conductive medium to absorb the exhaust heat emitted from the power converter 300, and convert it into electric power. Specifically, in one example, the thermal energy converter 400 may include a heat conductive medium passage 401, a valve 402, a turbine generator 403, and a condenser 404. The heat conductive medium passage 401 and the valve 402 integrally form a heat conductive medium flowing mechanism that allows the heat conductive medium to flow.

The heat conductive medium passages 401 are arranged adjacent to the power converter 300 with a predetermined array pitch and allow the heat conductive medium (e.g., water) to flow therethrough. The valve 402 is used for adjusting the flow rate of the heat conductive medium flowing through the heat conductive medium passage 401 and is controlled by the controller 500. The heat conductive medium that has absorbed heat while passing through the heat conductive medium passage 401 is transferred to the turbine generator 403, such that the turbine generator 403 is rotated and electric power is generated. The condenser 404 is configured to cool the heat conductive medium released from the turbine generator 403 and return it to the heat conductive medium passage 401. It should be noted that the turbine generator 403 is an example of the generator that generates electric power based on thermal energy retained by the heat conductive medium, and should not be limited thereto.

As stated above, the thermal energy converter 400 is configured such that its operation can be changed according to the intensity distribution of microwave energy from the satellite 100. Specifically, controlling the valve 402 can change the flow rate of the heat conductive medium flowing through each of the heat conductive medium passages 401 according to the microwave energy intensity distribution.

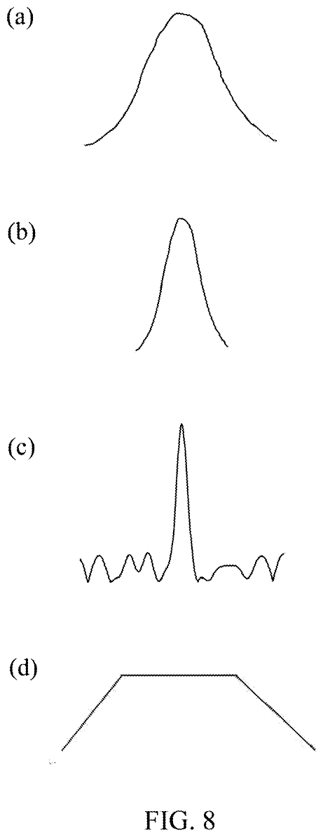

The intensity distribution of microwave energy transmitted from the satellite 100 is not uniform. The microwave energy intensity distribution may be an approximately Gaussian distribution as shown in FIG. 8(a) or may be a Dolph-Tschebyscheff array distribution as shown in FIG. 8(b). Further, as shown in FIG. 8(c), the microwave energy intensity distribution may include a main distribution at the center portion and also a distribution having sidelobes or grating lobes around the center portion, or further may have a trapezoid pattern as shown in FIG. 8(d). The form of the same Gaussian distribution may change depending on weather conditions, radio wave interference, or the like. When the microwaves have such a distribution, the power converter 300 may have a portion that generates much heat locally according to the distribution. Such local heat generation may reduce the performance of the power converter 300 and increase the exhaust heat from the power converter 300, leading to a lower energy conversion efficiency.

Thus, as described above, the controller 500 of the present embodiment controls the operation of the thermal energy converter 400 (specifically, the flow rate of the heat conductive medium flowing through the heat conductive medium passage 401) according to the microwave energy intensity distribution.

Various methods may be employed as a method for measuring a microwave energy intensity distribution. In one example, as shown in FIG. 3, the microwave energy intensity distribution may be estimated from a temperature distribution in an area near the power converter 300, which is measured by a temperature distribution calculator 520 based on the detection outputs from a large number of temperature sensors 510 disposed adjacent to the power converter 300. The controller 500 can change the flow rate of the heat conductive medium flowing through the heat conductive medium passage 401 according to the calculated temperature distribution. A larger amount of heat conductive medium is allowed to flow in a high-temperature area, which allows efficient conversion of the exhaust heat generated in the power converter 300 into electrical energy, thus increasing the overall energy conversion efficiency. Since this can suppress local heat generation in the power converter 300, it is possible to avoid a failure or deterioration of the circuit, and to improve the performance of the power converter 300. Although the example of disposing a large number of temperature sensors 510 near the surface of the power converter 300 has been described in the illustrated example, the measuring method is not limited to this. For example, a thermography camera that images the surface of the power converter 300 may be used.

When the thermal energy converter 400 is a thermoelectric converter as shown in FIG. 3, the thermoelectric converter may include a combining circuit 405 that combines generated power output by the thermal energy converter 400 and generated power output by the power converter 300. The resultant electric power output by the combining circuit 405 is obtained by combining not only the electric power produced by the power converter 300 but also the electric power obtained by converting the exhaust heat discharged from the power converter 300.

As described above, according to the space solar power system of the first embodiment, the exhaust heat from the power converter 300 can be used in the other form of energy, such as electrical energy, through conversion by the thermal energy converter 400. Thus, it is possible to provide a space solar power system having an increased energy conversion efficiency as compared to the conventional space solar power systems.

### Second Embodiment

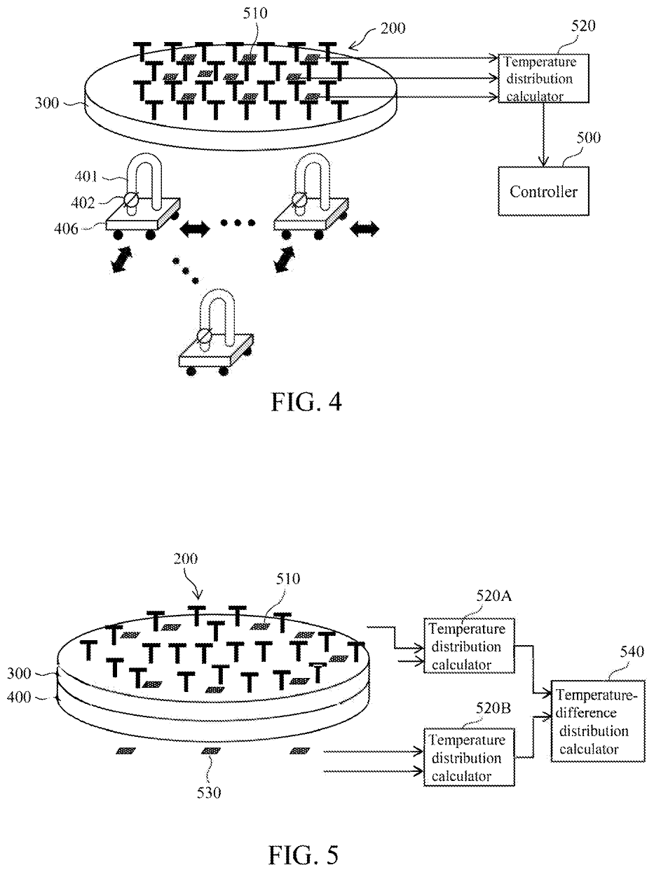

Next, referring to FIG. 4, a space solar power system (power receiving system) according to a second embodiment will be described. Since the overall configuration of the system is equal to that of the first embodiment (FIG. 1), repeated description will be omitted. FIG. 4 is a schematic diagram illustrating particularly a difference from the first embodiment. The configuration and operation of the portion not illustrated in the drawing are equal to those of the first embodiment.

In the second embodiment, the position of placement of the heat conductive medium passage 401 is controllable to change the operation of the thermal energy converter 400 according to the microwave energy intensity distribution. Specifically, in one example, the heat conductive medium passage 401 is placed on a moving table 406 near the power converter 300 (for example, below the power converter 300) and the position of the moving table 406 can be controlled according to a control signal from the controller 500. It should be noted that the moving table 406 may be an automated driving vehicle that is movable in any direction on the ground surface according to the control signal from the controller 500 as shown in FIG. 4, or may be a moving table that is movable only in one or two directions along a movement rail (not shown).

In this second embodiment, the controller 500 can control the position of the moving table 406 according to the result of calculation of the temperature distribution obtained by the temperature sensors 510. This can move the heat conductive medium passage 401 to a position where a large amount of heat is generated from the power converter 300, and can suppress local heat generation. Accordingly, also the second embodiment can produce the same effect as that of the first embodiment.

### Third Embodiment

Next, referring to FIG. 5, a space solar power system (power receiving system) according to a third embodiment will be described. Since the overall configuration of the system of the third embodiment is equal to that of the first embodiment (FIG. 1), repeated description will be omitted. FIG. 5 is a schematic diagram illustrating particularly a difference from the first embodiment. The configuration and operation of the portion not illustrated in the drawing are equal to those of the first embodiment.

The third embodiment differs from the forgoing embodiments in the configuration to measure temperature distributions in the power converter 300. Specifically, the system of the third embodiment is configured such that the temperature sensors 510 are disposed on the side adjacent to the front face of the power converter 300 (i.e., on the side where the receiving antennas 200 are arranged) and also temperature sensors 530 are disposed on the side adjacent to the rear face of the power converter 300, for example, in the vicinity of the ground. This means that the space solar power system of the present embodiment is configured to acquire temperature distribution data in two different areas and temperature difference data therebetween, and to execute control according to the obtained temperature difference.

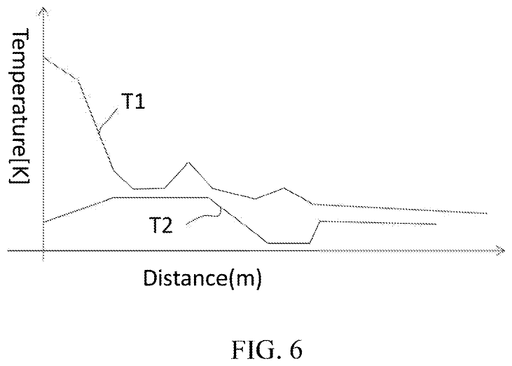

As shown in FIG. 6, temperature distributions (T1, T2) in two areas are calculated by temperature distribution calculators 520A, 520B, and a temperature difference distribution that is a difference between the two temperature distributions is calculated by a temperature difference distribution calculator 540. The controller 500 can control the operation of the thermal energy converter 400 by acquiring information about the temperature distributions in the power converter 300, in turn, information about the microwave energy intensity distribution according to the results of calculation by the temperature distribution calculator 520A, 520B and/or the temperature difference distribution calculator 540. Specifically, the controller 500 controls the thermal energy converter 400 to allow a larger amount of heat conductive medium to flow in an area with a larger difference between the temperature distributions T1 and T2. This can suppress local heat generation in the power converter 300. According to the third embodiment, not only with the temperature distributions in the power converter 300 but also with the temperature difference distribution in the areas, it is possible to more finely control the thermal energy converter 400 and to further increase the overall energy conversion efficiency. It should be noted that although the example of forming the temperature sensors 530 on the ground surface has been described above, the arrangement of the temperature sensors 530 is not limited thereto as long as the temperature sensors 530 can measure temperature distributions at positions different from the positions of the temperature sensors 510.

### Fourth Embodiment

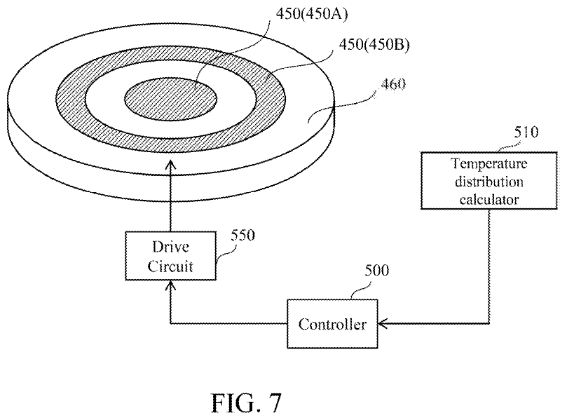

Next, referring to FIG. 7, a space solar power system (power receiving system) according to a fourth embodiment will be described. Since the overall configuration of the system of the fourth embodiment is equal to that of the first embodiment (FIG. 1), repeated description will be omitted. FIG. 7 is a schematic diagram illustrating particularly a difference from the first embodiment. The configuration and operation of the portion not illustrated in the drawing are equal to those of the first embodiment.

The fourth embodiment differs from the forgoing embodiments in that the thermal energy converter 400 includes a thermoelectric conversion element array 450 and a diffusing plate 460 and in that thermal energy is converted into electrical energy by thermoelectric conversion elements, not through thermal conversion using a heat conductive medium. The thermoelectric conversion element array 450 is an array of a large number of thermoelectric conversion elements formed by joining dissimilar semiconductors or metals. In the example of FIG. 7, the thermoelectric conversion element array 450 includes a first array 450A disposed at around the center of the thermal energy converter 400 and an array 450B of a donut shape that is concentrically arranged around the outer periphery of the first array 450A with a distance from the first array 450A. This is only an example of the thermoelectric conversion element array 450, and the thermoelectric conversion element array 450 should not be limited thereto. For example, the thermoelectric conversion element array 450 need not be concentric as shown in FIG. 7, and may be made up of a plurality of partial areas arranged in a grid manner.

The diffusing plate 460 is disposed around the thermoelectric conversion element array 450, and serves to diffuse microwaves and change the microwave energy intensity distribution.

The controller 500 controls ON/OFF of the thermoelectric conversion elements in the thermoelectric conversion element array 450 using a drive circuit 550 according to the result of calculation by the temperature distribution calculator 510. Accordingly, the controller 500 can control the operation of the thermal energy converter 400 according to the microwave energy intensity distribution, and thus increase the energy conversion efficiency of the system while suppressing local heat generation.

The output voltage (thermoelectromotive force) generated by the thermoelectric conversion element is expressed by V=S×ΔT (where V is the output voltage, ΔT is the temperature difference, and S is the Seebeck coefficient (with temperature dependence)), for example. The performance of the thermoelectric conversion element increases under the condition of a large Seebeck coefficient. This condition is achieved when the temperature is high, and thus when the temperature of the power receiving device is high, the conversion efficiency (in proportion to S) increases and the temperature difference (ΔT) from the low-temperature side (ground surface) increases. Consequently, the output voltage V increases. As such, in the fourth embodiment, the thermoelectric conversion element(s) in a portion having a large temperature difference (ΔT) is(are) turned ON and the thermoelectric conversion element(s) in a portion having a small temperature difference (ΔT) is(are) turned OFF so as to increase the thermoelectric conversion efficiency. It should be noted that instead of or in addition to the control using the drive circuit 550, the position of the thermoelectric conversion element array 450 and the position of the diffusing plate 460 may be controlled by using the moving table 406 as in the second embodiment.

### (Others)

Although various embodiments of the present disclosure have been described above, the present disclosure is not limited to the aforementioned embodiments, and includes a variety of variations. For example, although the aforementioned embodiments have been described in detail to clearly illustrate the present disclosure, the present disclosure need not include all of the structures described in the embodiments. It is possible to replace a part of a structure of an embodiment with a structure of another embodiment. In addition, it is also possible to add, to a structure of an embodiment, a structure of another embodiment. Further, it is also possible to, for a part of a structure of each embodiment, add, remove, or substitute a structure of another embodiment.

For example, in the aforementioned embodiments, the example of the thermal energy converter that is a thermoelectric converter converting thermal energy into electrical energy has been described. However, the thermal energy converter is not limited thereto, and may be a heat-heat converter that converts thermal energy into other types of thermal energy, or a device that converts thermal energy into mechanical energy. Specifically, for the thermal energy converter, other than the above-stated turbine generator and the thermoelectric converter, a gas turbine, a gas engine, a diesel engine, a fuel cell, a thermal converter, an absorption refrigerator that uses exhaust heat and the like may be employed. For example, the thermal energy converter may transmit thermal energy to a medium such as pentane having a low boiling point and generate power using a turbine driven by the vapor from the medium. Here, for the power generation system using the low boiling point medium, a binary generator may be used. Furthermore, a thermoacoustic generator that generates power by converting heat into sound waves or vibrations may be used. The thermoacoustic generator is useful for applications of the present invention since it can generate power at a low temperature of about 100° C. to 300° C. Also when the heat-heat converter is employed, the operation of the heat-heat converter is controlled based on the microwave energy intensity distribution as in the aforementioned embodiments. This can produce the same effect as that of the thermoelectric converter. In addition, the thermoelectric converter is not limited to a specific type, and various types of thermoelectric converters may be employed, such as the one using the Seebeck effect, the one using the spin Seebeck effect, and the like. Alternatively, a type of device that performs thermomagnetic generation using the Nernst effect or the spin Nernst effect may be employed.

In addition, although the above example states that the controller 500 controls the operation of the thermal energy converter 400 mainly by estimating a microwave energy intensity distribution according to the temperature distribution near the power converter 300, the measuring method is not limited to this. The microwave energy intensity distribution may be measured by measuring an intensity itself at each point of the microwaves. In addition, the controller 500 may acquire control information about the frequency converter circuit or the like of the satellite 100 so as to estimate an intensity distribution of the microwave energy transmitted from the satellite 100.

### DESCRIPTION OF SYMBOLS

100 Satellite
200 Receiving antenna
300 Power converter
400 Thermal energy converter
401 Heat conductive medium passage
402 Valve
403 Turbine generator
404 Condenser
405 Combining circuit
406 Moving table
450 Thermoelectric conversion element array
450A First array
450B Array
460 Diffusing plate
500 Controller
510, 530 Temperature sensor
520, 520A, 520B Temperature distribution calculator
540 Temperature difference distribution calculator
550 Drive circuit
600 Power grid (load)

What is claimed is:

1. A power receiving system comprising:
a power converter that receives electromagnetic waves transmitted from space and converts the electromagnetic waves into electric power;
a thermal energy converter that is disposed adjacent to the power converter and converts thermal energy generated in the power converter; and
a controller that controls operation of the thermal energy converter based on an energy intensity distribution of the electromagnetic waves.

2. The power receiving system according to claim 1, further comprising a temperature distribution calculator that calculates a temperature distribution near the power converter,
wherein the controller estimates an energy intensity distribution of the electromagnetic waves according to the temperature distribution and controls the operation of the thermal energy converter.

3. The power receiving system according to claim 2, wherein the temperature distribution calculator controls the operation of the thermal energy converter according to a temperature distribution in a first area near the power converter and a temperature distribution in a second area near the power converter, the second area being different from the first area.

4. The power receiving system according to claim 1, wherein the thermal energy converter is a thermoelectric converter that converts thermal energy into electric energy,
the power receiving system further comprising a combining circuit that combines electric power generated by the power converter and electric power generated by the thermoelectric converter.

5. The power receiving system according to claim 1,
wherein the thermal energy converter comprises a heat conductive medium flowing mechanism that allows a heat conductive medium to flow near the power converter and a generator that is driven by thermal energy of the heat conductive medium, and
wherein the controller controls flow of the heat conductive medium in the heat conductive medium flowing mechanism based on the energy intensity distribution.

6. The power receiving system according to claim 1,
wherein the thermal energy converter comprises a heat conductive medium flowing mechanism that allows a heat conductive medium to flow near the power converter and a generator that is driven by thermal energy of the heat conductive medium, and
wherein the controller controls a position of placement of the heat conductive medium flowing mechanism based on the energy intensity distribution.

7. The power receiving system according to claim 1,
wherein the thermal energy converter includes a thermoelectric conversion element array including thermoelectric conversion elements arranged therein, and
wherein the controller controls operation of the thermoelectric conversion elements based on the energy intensity distribution.

8. The power receiving system according to claim 7, wherein the thermal energy converter includes the thermoelectric conversion element array and a diffusing plate that is disposed around the thermoelectric conversion elements and diffuses the electromagnetic waves.
